(19) United States
(12) Patent Application Publication
(10) Pub. No.: US 2017/0176534 A1
(43) Pub. Date: Jun. 22, 2017

(54) SELF-CHARACTERIZING HIGH-SPEED COMMUNICATION INTERFACES

(71) Applicant: Intel Corporation, Santa Clara, CA (US)

(72) Inventors: Satheesh Chellappan, Folsom, CA (US); Sridharan Ranganathan, San Ramon, CA (US)

(21) Appl. No.: 14/975,691

(22) Filed: Dec. 18, 2015

(51) Int. Cl. G01R 31/317; G01R 31/3177

(52) U.S. Cl. CPC G01R 31/31724; G01R 31/31723; G01R 31/3177

(57) ABSTRACT

Logic controlling a local link interface enables in-band self-testing of the local link interface, the connected link interface of a remote device, and the link connecting the two. Logic configures a loopback in the remote device using an in-band protocol such as MIPI. The loopback may include all the link lanes or only a selected subset. The logic then isolates the local physical layer from upstream components and causes one or more test patterns to be sent through the local link interface and through the link to the loopback. The signals returning to the local link interface from the loopback are collected and compared with the original test patterns by an on-board checker in the link interface. The results, or a metric such as BER derived from the results, can then be accessed without requiring a custom dedicated test port.

### FIELD

Related fields include system-on-chip (SoC) testing, and more particularly, automated self-characterization of high-speed interfaces at the platform level as well as the SoC level.

### BACKGROUND

Performance margins of some SoC interfaces are affected by characteristics of the remote link, the connected device, and the system platform including other components on the destination board. Often the interoperability issues increase with the speed of the interface. Therefore, performance margins derived purely from SoC-level characterization of high-speed interface physical layers (such as MIPI M-PHY lanes) may not accurately reflect in-situ performance.

In the case of MIPI technology, the MIPI M-PHY specification defines a “compliance mode” and a “test mode.” However, taking advantage of these modes requires sequences to be executed at both ends of the link. This pre-supposes access to the assembled destination board with the SoC and peripheral chip installed and connected. This may generally be true in manufacturing or field service where the components and assembly configuration have already been fully developed and benchmarked. For SoCs being developed, a vertically-integrated company that is developing the SoC, the peripheral chip, and the destination board assembly might have this access earlier. However, a large sector of the electronics industry is not vertically integrated. One company may manufacture the SoC, another may manufacture the peripheral chip, and a third may provide the destination board where the SoC and peripheral are mounted and connected by a high-speed interface. Under these conditions, the logistics of in-situ testing may be difficult to coordinate.

Moreover, many peripheral or target devices such as XMM7260/7360 modems only support the method of enabling MPHY. Test mode that is described in the Super-Speed USB Inter-Chip (SSIC) specification. This presently does not include some potentially convenient and flexible features such as the ability to enable a loopback mode via registers. SSIC, Universal Flash Storage (UFS), and PCI Express Mini Card (PCIe-M) all include a capability to configure a remote device for target loopback, a convenient configuration for measuring the bit-error rate of a link. However, an external tester and special test-attach point may be needed to access the measured data. Some OEM SoC manufacturers characterize the operating margins of the high-speed interfaces by obtaining a sample of the destination board their customer will assemble and adapting the destination board to test the SoC in a nearly in situ configuration while providing the flexibility to, e.g., swap out chips or measure a variety of characteristics at selected points in the circuit. Often a test port on the destination board is connected to an external bit-error-rate tester (BERT). This approach does not require specific sequences to be performed by the remote peripheral device as the S SIC-specified test mode does. Instead, it relies on trigger signals from the external BERT. Tests that rely on external triggers may not access true “end-to-end” signaling from the SoC to the remote device.

The destination board adaptation to accommodate the BERT is a design task in itself, done separately for each different destination board design. This adaptation-for-testing design effort often cannot be leveraged for any other purpose except testing. The custom test setups for various different destination boards thus increase direct production costs as well as indirect costs associated with lengthening the production schedule. Therefore, a need exists for an effective manner to characterize high-speed interfaces without needing to accommodate an external BERT. The present disclosure addresses this need.

### BRIEF DESCRIPTION OF DRAWINGS

To facilitate understanding, identical reference numerals have been used, where possible, to designate identical elements that are common to the drawings. The drawings are not to scale and the relative dimensions of various elements in the drawings are depicted schematically and not necessarily to scale. The techniques of the present disclosure may readily be understood by considering the following detailed description in conjunction with the accompanying drawings, in which:

FIG. 1 is a block diagram of a system according to one embodiment;

FIG. 2 is a block diagram of a system according to one embodiment;

FIG. 3 is a block diagram of a system according to one embodiment;

FIG. 4 is a block diagram of a system-on-a-chip according to one embodiment;

FIG. 5 is a block diagram of a loopback test for links and interfaces;

FIG. 6 is a flowchart of a self-test process for a link interface in a system-on-chip (SoC);

FIG. 7 is a block diagram of a system-on-chip and a remote device linked for self-testing of the link interface;

FIG. 8 is a two-level timeline of additional details of an interaction between a SoC and a remote device during a self-test;

FIG. 9 is a state machine for link interface self-testing; and

FIG. 10 is a sub-state diagram for the PWM_SEQ state of the previous state diagram.

### DETAILED DESCRIPTION

In the following description, numerous specific details are set forth, such as examples of specific types of processors and system configurations, specific hardware structures, specific architectural and micro architectural details, specific register configurations, specific instruction types, specific system components, specific measurements/heights, specific processor pipeline stages and operation etcetera in order to provide a thorough understanding of the present disclosure. It will be apparent, however, to one skilled in the art that these specific details need not be employed to practice the present disclosure. In other instances, well known components or methods, such as specific and alternative processor architectures, specific logic circuits/code for described algorithms, specific firmware code, specific interconnect operation, specific logic configurations, specific manufacturing techniques and materials, specific compiler implementations, specific expression of algorithms in code, specific power down and gating techniques/logic and other specific operational details of computer system haven't been described in detail in order to avoid unnecessarily obscuring the present disclosure.

Although the following embodiments may be described with reference to energy conservation and energy efficiency in specific integrated circuits, such as in computing platforms or microprocessors, other embodiments are applicable to other types of integrated circuits and logic devices. Similar techniques and teachings of embodiments described herein may be applied to other types of circuits or semiconductor devices that may also benefit from better energy efficiency and energy conservation. For example, the disclosed embodiments are not limited to desktop computer systems or Ultrabooks™. And may be also used in other devices, such as handheld devices, tablets, other thin notebooks, systems on a chip (SOC) devices, and embedded applications. Some examples of handheld devices include cellular phones, Internet protocol devices, digital cameras, personal digital assistants (PDAs), and handheld PCs. Embedded applications typically include a microcontroller, a digital signal processor (DSP), a system on a chip, network computers (NetPC), set-top boxes, network hubs, wide area network (WAN) switches, or any other system that may perform the functions and operations taught below. Moreover, the apparatus', methods, and systems described herein are not limited to physical computing devices, but may also relate to software optimizations for energy conservation and efficiency. As will become readily apparent in the description below, the embodiments of methods, apparatus', and systems described herein (whether in reference to hardware, firmware, software, or a combination thereof) are vital to a ‘green technology’ future balanced with performance considerations.

As computing systems are advancing, the components therein are becoming more complex. As a result, the interconnect architecture to couple and communicate between the components is also increasing in complexity to ensure bandwidth requirements are met for optimal component operation. Furthermore, different market segments demand different aspects of interconnect architectures to suit the market's needs. For example, servers require higher performance, while the mobile ecosystem is sometimes able to sacrifice overall performance for power savings. Yet, it's a singular purpose of most fabrics to provide highest possible performance with maximum power saving. Below, a number of interconnects are discussed, which would potentially benefit from aspects of the disclosure described herein.

Note that the apparatus, methods, and systems described above may be implemented in any electronic device or system as aforementioned. As specific illustrations, the figures below provide exemplary systems for utilizing the invention as described herein. As the systems below are described in more detail, a number of different interconnects are disclosed, described, and revisited from the discussion above. And as is readily apparent, the advances described above may be applied to any of those interconnects, fabrics, or architectures.

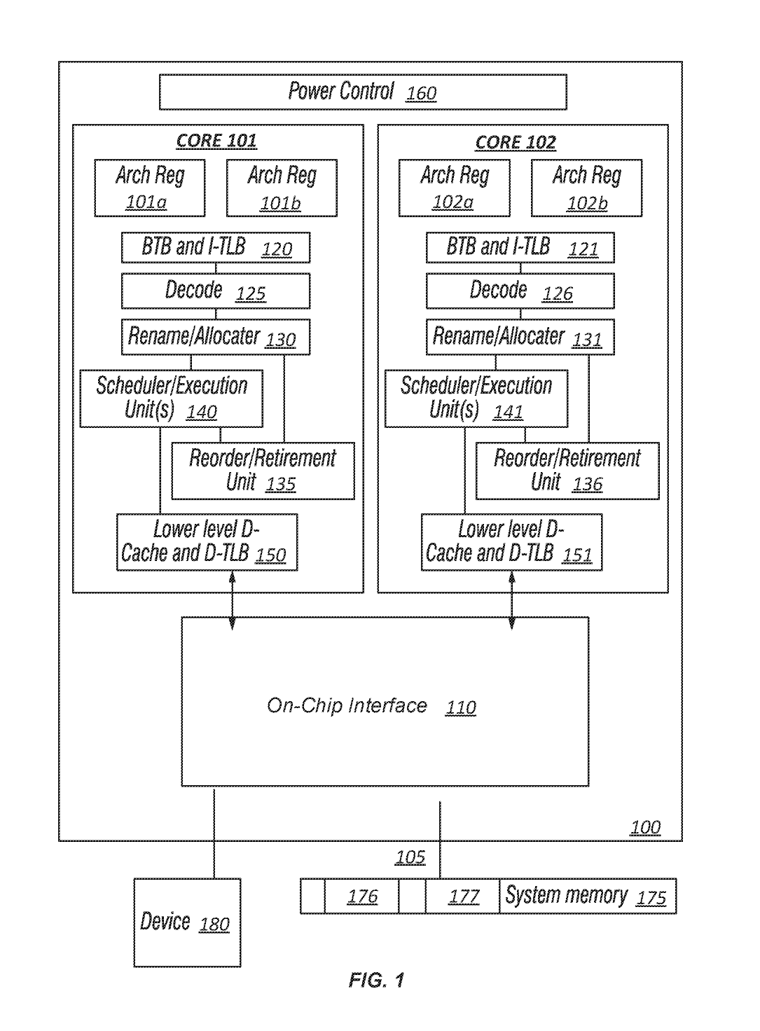

Referring to FIG. 1, an embodiment of a block diagram for a computing system including a multicore processor is depicted. Processor 100 includes any processor or processing device, such as a microprocessor, an embedded processor, a digital signal processor (DSP), a network processor, a handheld processor, an application processor, a co-processor, a system on a chip (SOC), or other device to execute code. Processor 100, in one embodiment, includes at least two cores—core 101 and 102, which may include asymmetric cores or symmetric cores (the illustrated embodiment). However, processor 100 may include any number of processing elements that may be symmetric or asymmetric.

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core often refers to logic located on an integrated circuit capable of maintaining an independent architectural state, wherein each independently maintained architectural state is associated with at least some dedicated execution resources. In contrast to cores, a hardware thread typically refers to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

Physical processor 100, as illustrated in FIG. 1, includes two cores—core 101 and 102. Here, core 101 and 102 are considered symmetric cores, i.e. cores with the same configurations, functional units, and/or logic. In another embodiment, core 101 includes an out-of-order processor core, while core 102 includes an in-order processor core. However, cores 101 and 102 may be individually selected from any type of core, such as a native core, a software managed core, a core adapted to execute a native Instruction Set Architecture (ISA), a core adapted to execute a translated Instruction Set Architecture (ISA), a co-designed core, or other known core. In a heterogeneous core environment (i.e. asymmetric cores), some form of translation, such a binary translation, may be utilized to schedule or execute code on one or both cores. Yet to further the discussion, the functional units illustrated in core 101 are described in further detail below, as the units in core 102 operate in a similar manner in the depicted embodiment.

As depicted, core 101 includes two hardware threads 101a and 101b, which may also be referred to as hardware thread slots 101a and 101b. Therefore, software entities, such as an operating system, in one embodiment potentially view processor 100 as four separate processors, i.e., four logical processors or processing elements capable of executing four software threads concurrently. As alluded to above, a first thread is associated with architecture state registers 101a, a second thread is associated with architecture state registers 101b, a third thread may be associated with architecture state registers 102a, and a fourth thread may be associated with architecture state registers 102b. Here, each of the architecture state registers (101a, 101b, 102a, and 102b) may be referred to as processing elements, thread slots, or thread units, as described above. As illustrated, architecture state registers 101a are replicated in architecture state registers 101b, so individual architecture states/contexts are capable of being stored for logical processor 101a and logical processor 101b. In core 101, other smaller resources, such as instruction pointers and renaming logic in allocator and renamer block 130 may also be replicated for threads 101a and 101b. Some resources, such as re-order buffers in reorder/retirement unit 135, ILTB 120, load/store buffers, and queues may be shared through partitioning. Other resources, such as general purpose internal registers, page-table base register(s), low-level data-cache and data-TLB 115, execution unit(s) 140, and portions of out-of-order unit 135 are potentially fully shared.

Processor 100 often includes other resources, which may be fully shared, shared through partitioning, or dedicated by/to processing elements. In FIG. 1, an embodiment of a purely exemplary processor with illustrative logical units/resources of a processor is illustrated. Note that a processor may include, or omit, any of these functional units, as well as include any other known functional units, logic, or firmware not depicted. As illustrated, core 101 includes a simplified, representative out-of-order (OOO) processor core. But an in-order processor may be utilized in different embodiments. The OOO core includes a branch target buffer 120 to predict branches to be executed/taken and an instruction-translation buffer (I-TLB) 120 to store address translation entries for instructions.

Core 101 further includes decode module 125 coupled to fetch unit 120 to decode fetched elements. Fetch logic, in one embodiment, includes individual sequencers associated with thread slots 101a, 101b, respectively. Usually core 101 is associated with a first ISA, which defines/specifies instructions executable on processor 100. Often machine code instructions that are part of the first ISA include a portion of the instruction (referred to as an opcode), which references/specifies an instruction or operation to be performed. Decode logic 125 includes circuitry that recognizes these instructions from their opcodes and passes the decoded instructions on in the pipeline for processing as defined by the first ISA. For example, as discussed in more detail below decoders 125, in one embodiment, include logic designed or adapted to recognize specific instructions, such as transactional instruction. As a result of the recognition by decoders 125, the architecture or core 101 takes specific, predefined actions to perform tasks associated with the appropriate instruction. It is important to note that any of the tasks, blocks, operations, and methods described herein may be performed in response to a single or multiple instructions; some of which may be new or old instructions. Note decoders 126, in one embodiment, recognize the same ISA (or a subset thereof). Alternatively, in a heterogeneous core environment, decoders 126 recognize a second ISA (either a subset of the first ISA or a distinct ISA).

In one example, allocator and renamer block 130 includes an allocator to reserve resources, such as register files to store instruction processing results. However, threads 101a and 101b are potentially capable of out-of-order execution, where allocator and renamer block 130 also reserves other resources, such as reorder buffers to track instruction results. Unit 130 may also include a register renamer to rename program/instruction reference registers to other registers internal to processor 100. Reorder/retirement unit 135 includes components, such as the reorder buffers mentioned above, load buffers, and store buffers, to support out-of-order execution and later in-order retirement of instructions executed out-of-order.

Scheduler and execution unit(s) block 140, in one embodiment, includes a scheduler unit to schedule instructions/operation on execution units. For example, a floating point instruction is scheduled on a port of an execution unit that has an available floating point execution unit. Register files associated with the execution units are also included to store information instruction processing results. Exemplary execution units include a floating point execution unit, an integer execution unit, a jump execution unit, a load execution unit, a store execution unit, and other known execution units.

Lower level data cache and data translation buffer (D-TLB) 150 are coupled to execution unit(s) 140. The data cache is to store recently used/operated on elements, such as data operands, which are potentially held in memory coherency states. The D-TLB is to store recent virtual/linear to physical address translations. As a specific example, a processor may include a page table structure to break physical memory into a plurality of virtual pages.

Here, cores 101 and 102 share access to higher-level or further-out cache, such as a second level cache associated with on-chip interface 110. Note that higher-level or further-out refers to cache levels increasing or getting further way from the execution unit(s). In one embodiment, higher-level cache is a last-level data cache—last cache in the memory hierarchy on processor 100—such as a second or third level data cache. However, higher level cache is not so limited, as it may be associated with or includes an instruction cache. A trace cache—a type of instruction cache—instead may be coupled after decoder 125 to store recently decoded traces. Here, an instruction potentially refers to a macro-instruction (i.e. a general instruction recognized by the decoders), which may decode into a number of micro-instructions (micro-operations).

In the depicted configuration, processor 100 also includes on-chip interface module 110. Historically, a memory controller, which is described in more detail below, has been included in a computing system external to processor 100. In this scenario, on-chip interface 110 is to communicate with devices external to processor 100, such as system memory 175, a chipset (often including a memory controller hub to connect to memory 175 and an I/O controller hub to connect peripheral devices), a memory controller hub, a northbridge, or other integrated circuit. And in this scenario, bus 105 may include any known interconnect, such as multi-drop bus, a point-to-point interconnect, a serial interconnect, a parallel bus, a coherent (e.g. cache coherent) bus, a layered protocol architecture, a differential bus, and a GTL bus.

Memory 175 may be dedicated to processor 100 or shared with other devices in a system. Common examples of types of memory 175 include DRAM, SRAM, non-volatile memory (NV memory), and other known storage devices. Note that device 180 may include a graphic accelerator, processor or card coupled to a memory controller hub, data storage coupled to an I/O controller hub, a wireless transceiver, a flash device, an audio controller, a network controller, or other known device.

Recently however, as more logic and devices are being integrated on a single die, such as SOC, each of these devices may be incorporated on processor 100. For example, in one embodiment, a memory controller hub is disposed on the same package and/or die as processor 100. Here, a portion of the core (an on-core portion) 110 includes one or more controller(s) for interfacing with other devices such as memory 175 or a graphics device 180. The configuration including an interconnect and controllers for interfacing with such devices is often referred to as an on-core (or un-core configuration). As an example, on-chip interface 110 includes a ring interconnect for on-chip communication and a high-speed serial point-to-point link 105 for off-chip communication. Yet, in the SOC environment, even more devices, such as the network interface, co-processors, memory 175, graphics processor 180, and any other known computer devices/interface may be integrated on a single die or integrated circuit to provide small form factor with high functionality and low power consumption.

In one embodiment, processor 100 is capable of executing a compiler, optimization, and/or translator code 177 to compile, translate, and/or optimize application code 176 to support the apparatus and methods described herein or to interface therewith. A compiler often includes a program or set of programs to translate source text/code into target text/code. Usually, compilation of program/application code with a compiler is done in multiple phases and passes to transform hi-level programming language code into low-level machine or assembly language code. Yet, single pass compilers may still be utilized for simple compilation. A compiler may utilize any known compilation techniques and perform any known compiler operations, such as lexical analysis, preprocessing, parsing, semantic analysis, code generation, code transformation, and code optimization.

Larger compilers often include multiple phases, but most often these phases are included within two general phases: (1) a front-end, i.e. generally where syntactic processing, semantic processing, and some transformation/optimization may take place, and (2) a back-end, i.e. generally where analysis, transformations, optimizations, and code generation takes place. Some compilers refer to a middle, which illustrates the blurring of delineation between a front-end and back end of a compiler. As a result, reference to insertion, association, generation, or other operation of a compiler may take place in any of the aforementioned phases or passes, as well as any other known phases or passes of a compiler. As an illustrative example, a compiler potentially inserts operations, calls, functions, etcetera in one or more phases of compilation, such as insertion of calls/operations in a front-end phase of compilation and then transformation of the calls/operations into lower-level code during a transformation phase. Note that during dynamic compilation, compiler code or dynamic optimization code may insert such operations/calls, as well as optimize the code for execution during runtime. As a specific illustrative example, binary code (already compiled code) may be dynamically optimized during runtime. Here, the program code may include the dynamic optimization code, the binary code, or a combination thereof.

Similar to a compiler, a translator, such as a binary translator, translates code either statically or dynamically to optimize and/or translate code. Therefore, reference to execution of code, application code, program code, or other software environment may refer to: (1) execution of a compiler program(s), optimization code optimizer, or translator either dynamically or statically, to compile program code, to maintain software structures, to perform other operations, to optimize code, or to translate code; (2) execution of main program code including operations/calls, such as application code that has been optimized/compiled; (3) execution of other program code, such as libraries, associated with the main program code to maintain software structures, to perform other software related operations, or to optimize code; or (4) a combination thereof.

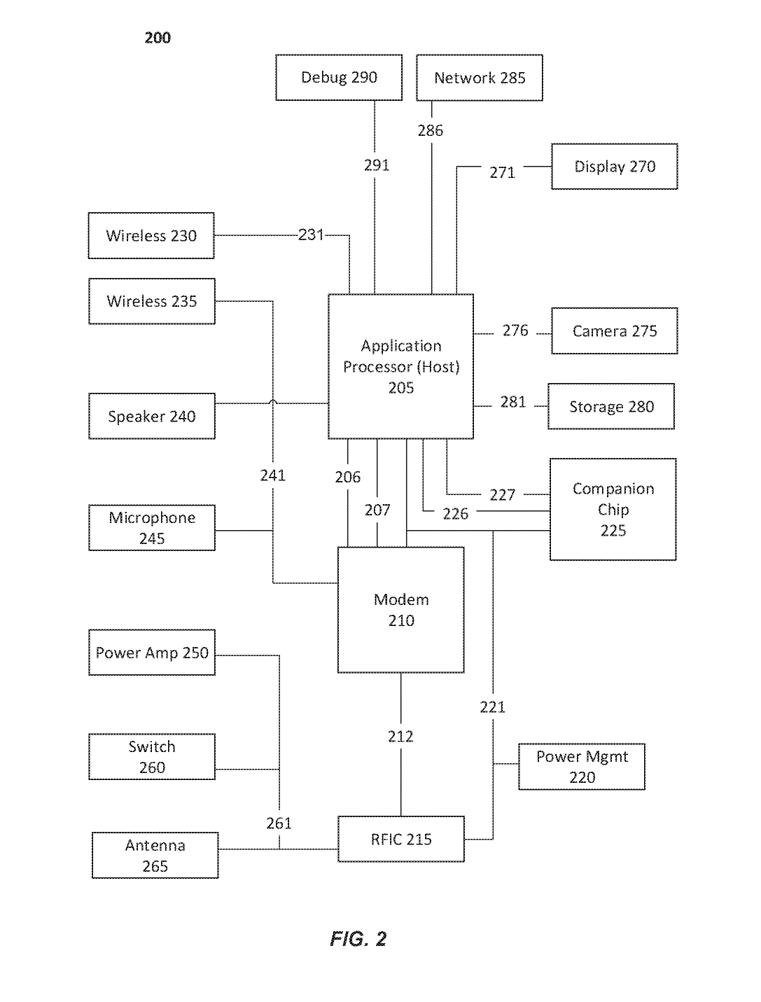

Referring to FIG. 2, an embodiment of a low power computing platform is depicted. In one embodiment, low power computing platform 200 includes a user endpoint, such as a phone, smartphone, tablet, ultraportable notebook, a notebook, a desktop, a server, a transmitting device, a receiving device, or any other known or available computing platform. The illustrated platform depicts a number of different interconnects to couple multiple different devices. Exemplary discussion of these interconnect are provided below to provide options on implementation and inclusion. However, a low power platform 200 is not required to include or implement the depicted interconnects or devices. Furthermore, other devices and interconnect structures that are not specifically shown may be included.

Starting at the center of the diagram, platform 200 includes application processor 205. Often this includes a low power processor, which may be a version of a processor configuration described herein or known in the industry. As one example, processor 200 is implemented as a system on a chip (SoC). As a specific illustrative example, processor 200 includes an Intel® Architecture Core™-based processor such as an i3, i5, i7 or another such processor available from Intel Corporation, Santa Clara, Calif. However, understand that other low power processors such as available from Advanced Micro Devices, Inc. (AMD) of Sunnyvale, Calif., a MIPS-based design from MIPS Technologies, Inc. of Sunnyvale, Calif., an ARM-based design licensed from ARM Holdings, Ltd. or customer thereof, or their licensees or adopters may instead be present in other embodiments such as an Apple A5/A6 processor, a Qualcomm Snapdragon processor, or TI OMAP processor.

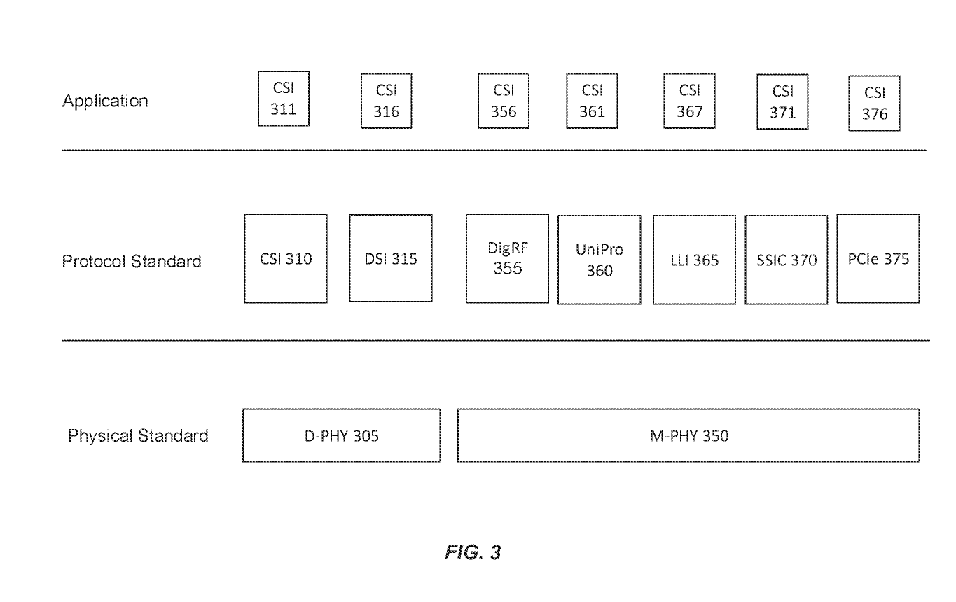

FIG. 3 is a diagram illustrating an embodiment of a low power data transmission platform. As shown, an application layer, protocol standard layer, and physical standard layer are displayed in the figure. In particular, the application layer provides various instances of a camera serial interface (CSI)—311, 316, 356, 361, 367, 371, and 376. Notably, CSI may include a unidirectional differential serial interface to transmit data and clock signals.

The protocol standard layer includes another instance of a CSI interface 310 and a Digital Serial Interface (DSI) 315. DSI may define a protocol between a host processor and a peripheral device using a D-PHY physical interface. In addition, the protocol standard layer includes a DigRF interface 355, UniPro interface 360, Low Latency Interface (LLI) 365, SuperSpeed Inter-Chip (SSIC) interface 370, and Peripheral Component Interconnect Express (PCIe) 375 interface.

Lastly, the physical standard layer provides a D-PHY 305 sub-layer. It may be understood by one having ordinary skill in the art that D-PHY includes a physical layer solution upon which MIPI camera interfaces, display serial interfaces, and general purpose high-speed/low-power interfaces are based. In addition, the physical standard layer includes a M-PHY sub-layer 350 which is the successor of D-PHY, requiring less pins and providing more bandwidth per pin (pair) with improved power efficiency.

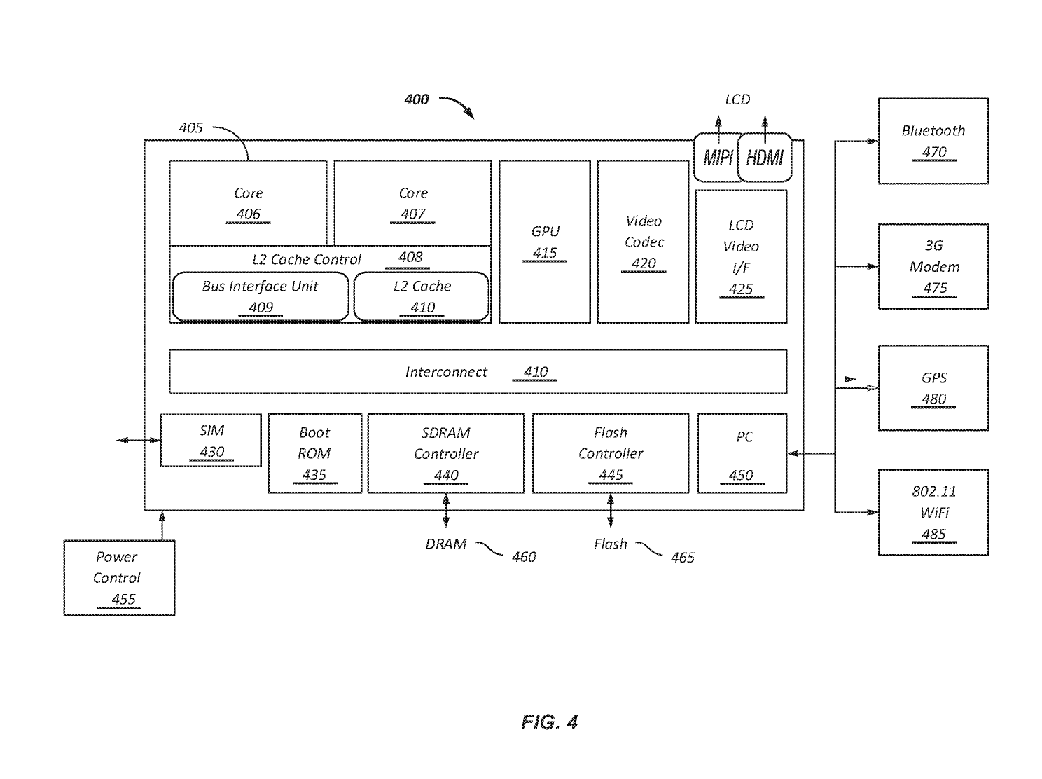

Turning next to FIG. 4, an embodiment of a system on-chip (SOC) design in accordance with the inventions is depicted. As a specific illustrative example, SOC 400 is included in user equipment (UE). In one embodiment, UE refers to any device to be used by an end-user to communicate, such as a hand-held phone, smartphone, tablet, ultra-thin notebook, notebook with broadband adapter, or any other similar communication device. Often a UE connects to a base station or node, which potentially corresponds in nature to a mobile station (MS) in a GSM network.

Here, SOC 400 includes 2 cores—406 and 407. Similar to the discussion above, cores 406 and 407 may conform to an Instruction Set Architecture, such as an Intel® Architecture Core™-based processor, an Advanced Micro Devices, Inc. (AMD) processor, a MIPS-based processor, an ARM-based processor design, or a customer thereof, as well as their licensees or adopters. Cores 406 and 407 are coupled to cache control 408 that is associated with bus interface unit 409 and L2 cache 410 to communicate with other parts of system 400. Interconnect 490 includes an on-chip interconnect, such as an IOSF, AMBA, or other interconnect discussed above, which potentially implements one or more aspects of the described invention.

Interface 410 provides communication channels to the other components, such as a Subscriber Identity Module (SIM) 430 to interface with a SIM card, a boot rom 435 to hold boot code for execution by cores 406 and 407 to initialize and boot SOC 400, a SDRAM controller 440 to interface with external memory (e.g. DRAM 460), a flash controller $N45 to interface with non-volatile memory (e.g. Flash 465), a peripheral control 450 (e.g. Serial Peripheral Interface) to interface with peripherals, video codecs 420 and video interface 425 to display and receive input (e.g. touch enabled input), GPU 415 to perform graphics related computations, etc. Any of these interfaces may incorporate aspects of the invention described herein.

In addition, the system illustrates peripherals for communication, such as a Bluetooth module 470, SDRAM Controller 440, Video Codec 420, Power Control 455, 3G modem 475, GPS 480, and WiFi 485. Note as stated above, a UE includes a radio for communication. As a result, these peripheral communication modules are not all required. However, in a UE some form a radio for external communication is to be included.

Interfaces with built-in self-test capability can perform SoC self-margining at virtually any point in the development cycle or product life. Because the hardware and logic is built into the SoC, the link self-test needs no external input or designated tester. Because the self-test process isolates the interface from the SoC controller(s), it is agnostic to controller protocol and does not need to be changed to accommodate different controllers. The ability to run standard test patterns such as Compliant Random Pattern (CRPAT) and Compliant Jitter Tolerance Pattern (CJTPAT) enables comparisons with measurements made by others of the same patterns on similar interfaces.

Because any subset of a set of lanes may be tested separately, the self-testing approach is scalable and the testing of any number of data lines can be included in a single one sequential test. A self-test feature could replace or extend sort and class testing done at the silicon stage. The ability of the assembly supplier to identify the physical-layer parameters that match the platform design may enable faster platform integration. Because of the obviated need for design, assembly and validation of dedicated test structures, self-testing interfaces may lower the cost and shorten the schedule for development.

The following terms shall have the following meanings for purposes of this document:

BERT: Bit Error Rate Tester.

CRPAT, CJTPAT, LFSR: Types of test patterns, namely Compliant Random Pattern, Compliant Jitter Tolerance Pattern, and Linear Feedback Shift Register.

EMI: Electromagnetic interference.

HS Mode: High-Speed Mode; one of the possible operating speeds of a link interface, often a burst mode.

MIPI: Mobile Industry Processing Interface.

PWM Mode: A pulse-width modulation mode available for some link interfaces, often slower than full operating speed; may be used for configuration.

RMMI: Reference M-PHY Module Interface, part of the MIPI specification.

RRAP: Remote register access protocol.

SoC: System-on-chip including, at a minimum, a controller and a link interface.

SSIC: Super-Speed Inter-Chip

One choice of remote device to test with the SoC chip is a chip to be located next to the SoC chip on the destination board. Alternatively, the most distant chip to be connected to the SoC, which may have the most opportunity for link errors, may be selected for testing. If a different chip may have more link errors for some other reason, such as crosstalk, EMI, or dynamic temperature gradients in its planned location, that chip may be useful to test as a worst case.

Many of the disclosed examples relate directly to SSIC/MIPI configurations with no required modifications to the SSIC devices. Other types of configurations with similar link interfaces may be set up for self-testing without undue experimentation. Additionally or alternatively, the in-band PWM RRAP packets may be decoded to accommodate non-SSIC devices and enable them to enter an appropriate loopback mode.

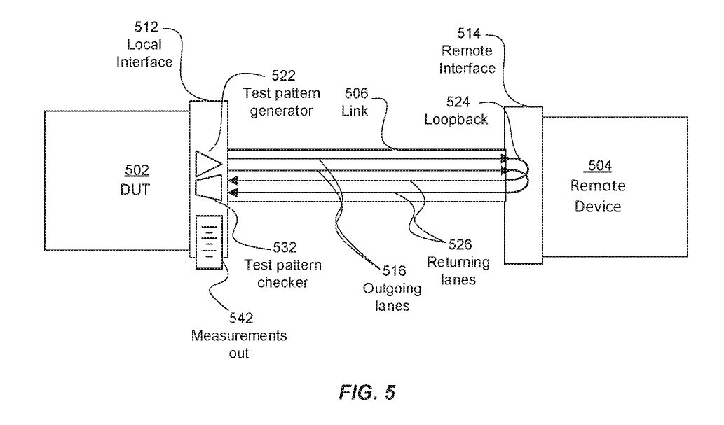

FIG. 5 is a block diagram of a loopback test for links and interfaces. This basic arrangement isolates errors that originate in the link lanes or either of the link interfaces. Device under test (DUT) 502 generates test patterns in test pattern generator 522 and transmits them through outgoing lanes 516 of link 506. Remote link interface 514 of remote device 504 acts as a loopback 524, receiving the test patterns from incoming lanes 516 and routing them into returning lanes 526. Local interface 512 receives the test patterns from returning lanes 526. Test pattern checker 532 compares the returning test patterns with the original test patterns generated in test pattern generator 522 and derives measurements, for example bit-error rate (BER). The measurements may be accessed through measurement output 542.

Preferably, the self-test can be controlled in-band and wholly by the device under test. This could be approached by using a protocol understood by the device under test and at least one representative remote device. For example, Mobile Industry Processing Interface (MIPI) is an in-band protocol widely used for chip-to-chip communication. However, the disclosed methods readily adapt to other in-band protocols that enable a link interface on one end of a link to configure a loopback in a link interface on the other end of the link.

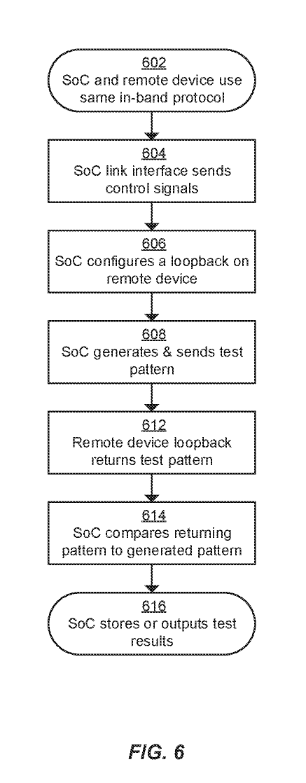

FIG. 6 is a flowchart of a self-test process for a link interface in a system-on-chip (SoC). At step 602, a SoC and a connected remote device use the same in-band protocol for configuration. At step 604, the SoC link interface arranges to send control signals to the remote device. At step 606, the SoC configures a loopback on remote device. At step 608, the SoC generates & sends a test pattern of pulses or bursts designed to reveal the performance margins of the link. At step 612, the loopback on the remote device returns the test pattern, providing a round-trip measurement of any or all the lanes of the link. At step 614, the SoC compares the returning pattern from the loopback to the original generated pattern and derives a bit-error rate (BER) or other quality metric. At step 616, the SoC stores or outputs the derived test results.

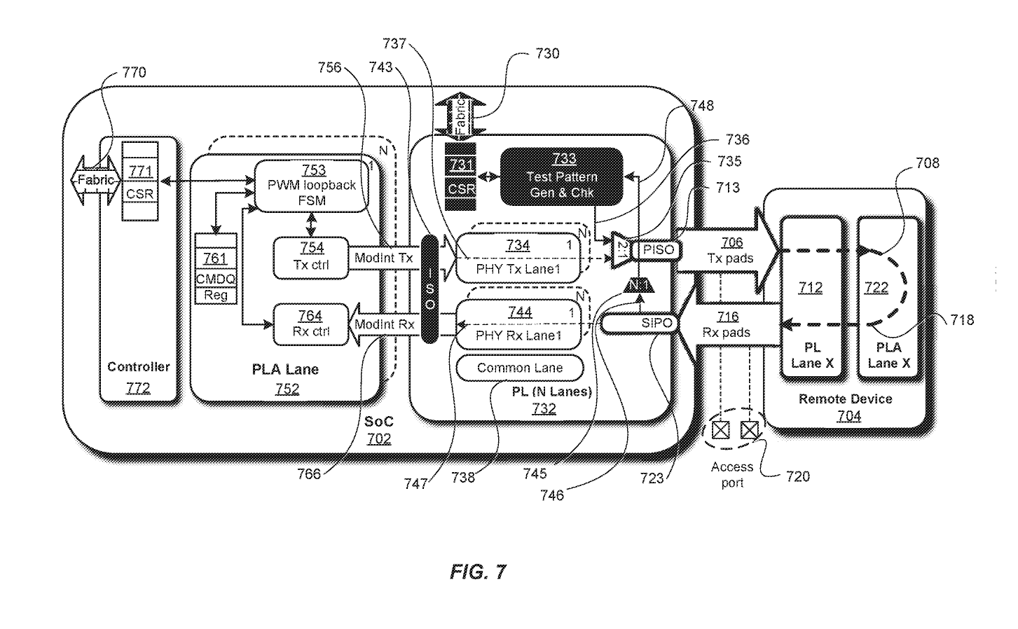

FIG. 7 is a block diagram of a system-on-chip and a remote device linked for self-testing of the link interface. For example, the link interface may include a MIPI M-PHY controller driving one or more M-PHY data lanes to configure the remote device for MIPI loopback mode in compliance with adopted standards. SoC 702 is linked to remote device 704 by transmit pad 706 and receive pad 716. Some of the functional blocks that implement the link interface self-testing include pulse-width modulation loopback finite state machine (PWM loopback FSM) 753, isolator 743, test pattern generator and checker 733, Parallel-In, Serial-Out (PISO) 713, Serial-In, Parallel-Out (SIPO) 723, 2:1 demultiplexer 735, and N:1 demultiplexer 745, Control and Status Registers (CSRs) 731 and 771, and command queue (CMDQ) register 761.

PWM loopback FSM 753 may include a master state machine that sequences the self-test. After an initial reset, the link interface, including SoC physical layer 732 and SoC physical-layer adapter 752, prepares to program the remote device 704 to set up the loopback that deflects test signal 708 into returning signal 718. In some embodiments the preparation may include SoC physical layer 732 and SoC physical-layer adapter 752 entering the low-speed PWM mode and executing the in-band programming of the remote physical layer 712 and the remote physical-layer adapter 722 at a reduced speed. Command queue (CMDQ) register 761 may hold the command sequences to be retrieved by PWM loopback FSM 753 and sent to transmitter controller 754. At this point in the process, isolator 743 is inactive and the commands can be relayed through transmit module interface 756 (e.g., an RMMI) to PHY transmit lanes 734. In some embodiments, each PHY transmit lane 734 may have its own dedicated physical-layer adapter 752. The commands may enter PHY transmit lanes 734 as transmitter controller signal 737 and pass through 2:1 demultiplexer 735 to be serialized by Parallel-In, Serial-Out (PISO) 713. The serialized signal traverses transmit pad 706 to enter remote physical layer 712 on remote device 704. There, remote physical layer 712 and remote physical-layer adapter 722 construct the loopback path for test signal 708 and returning signal 718.

Configuration acknowledgments and any other responses from remote device 704 return to SoC 702 by way of receive pad 716 to be parallelized by Serial-In, Parallel-Out (SIPO) 723. The parallelized signals 1-N then traverse PHY receive lanes 744 as receiver controller signals 747. With isolator 743 inactive, receiver controller signals 747 pass through receive module interface 766 and into receiver controller 764 on SoC physical-layer adapter 752. Receiver controller 764 communicates the responses of remote device 704 to PWM loopback FSM 753. The signals sent and received during the construction of the loopback may be captured in Control and Status Register (CSR) 771 for eventual readout through fabric connection 770.

After the loopback is established at remote device 704, SoC physical layer 732 (or, alternatively, SoC physical-layer adapter 752 depending on the embodiment) activates isolator 743. Isolator 743 communicatively decouples the SoC physical layer 732 from the upstream SoC physical-layer adapter 752, the SoC controller 772, and any other upstream components so that only the link and the loopback affect the bit-error rate measurement. Test pattern generator and checker 733 begins generating test patterns to transmit as test signal 708 and checking the patterns that re-enter SoC physical layer 732 as returning signal 718. Test pattern generator and checker 733 may be a single module or a separate generator and checker. In some embodiments, SoC physical layer 732 and SoC physical-layer adapter 752, along with remote physical layer 712 and remote physical-layer adapter 722, may be put into a high-speed (HS) mode to run the test patterns at full operating speed.

From test pattern generator and checker 733, test pattern 736 passes through 2:1 demultiplexer 735 to be serialized by Parallel-In, Serial-Out (PISO) 713. The serialized signal traverses transmit pad 706 to enter remote physical layer 712 on remote device 704. There, test pattern 708 travels around the loopback and becomes returning pattern 718, which returns to SoC 702 via receive pad 716. Returning pattern 718 is parallelized by Serial-In, Parallel-Out (SIPO) 723. The parallelized signals 746 are combined by N:1 demultiplexer 745. Combined returning test pattern 748 enters test pattern generator and checker 733 to be checked and compared with test pattern 736 to calculate bit-error rate and other margining parameters. The test results are captured in Control and Status Register (CSR) 731 for eventual readout through fabric connection 730.

Common lane 738 is not included in the testing because it carries a DC signal. Access port 720 tapping into transmit pad 706 and receive pad 716 may be used to independently monitor traffic through the pads and validate the register data. In some embodiments, self-testing may obviate the need for test access port 720; in others, it may be used for validating the self-test.

In some embodiments, 2:1 demultiplexer 735, PISO 713, transmit pad 706, remote physical layer 712, remote physical-layer adapter 722, loopback 708+718, receive pad 716, and SIPO 723 may be active during both the in-band programming phase and the testing phase. In some embodiments, fabric connection 770, CSR 771, CMDQ 761, PWM loopback FSM 753, transmitter controller 754, transmit module interface 756, transmit lanes 734, receive lanes 744, receive module interface 766, and receiver controller 764 may only be active for the in-band programming phase. In some embodiments, fabric connection 730, CSR 731, isolator 743, test pattern generator and checker 733, and N:1 demultiplexer 745 may only be active for the test-pattern checking phase.

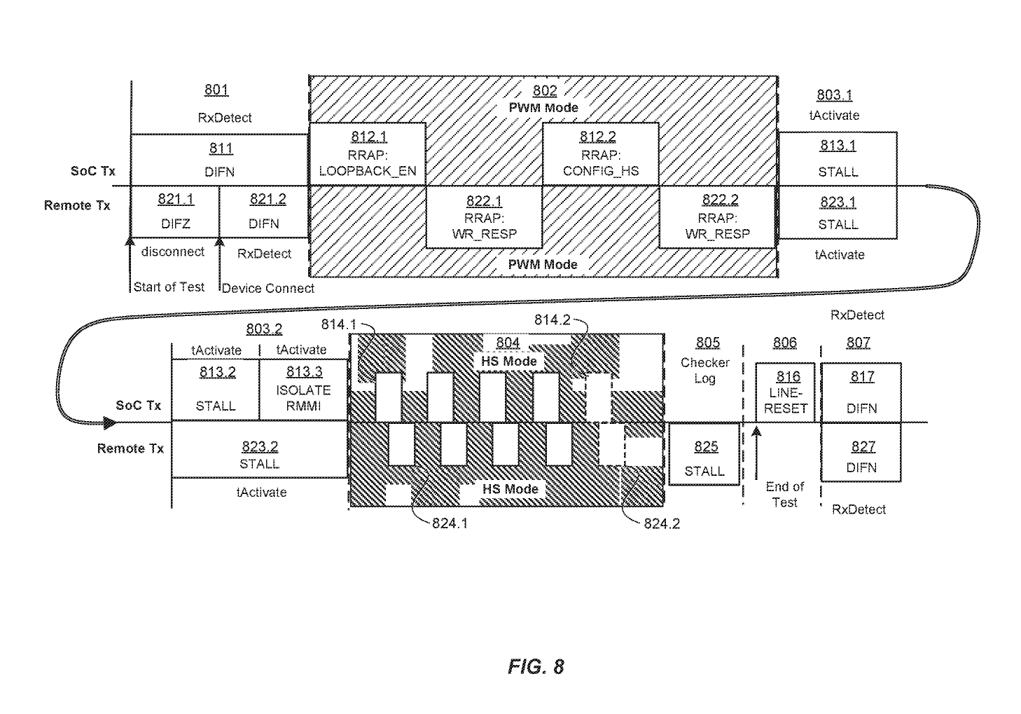

FIG. 8 is a two-level timeline of additional details of an interaction between a SoC and a remote device during a self-test. This procedure replaces the setup and configuration processes previously performed using an external BERT. The present disclosure incorporates all the necessary setup and configuration feature within the SoC thereby eliminating the need for an external tester. On the diagram, the centerlines of the two contiguous sections represent time, which increases from left to right. Actions shown above the centerline are done by the SoC whereas actions shown below the centerline are done by the remote device.

In phase 801, the SoC (top line) initiates the connection by driving a DIF-N signal 811 on its transmit pads. Initially the remote device is disconnected and is in a DIF-Z hibernate mode 821.1. In response to DIF-N signal 811, the remote device exits the hibernate mode and responds by driving DIF-N 821.2 to indicate connection.

Both the SoC and the remote device may then enter PWM mode for phase 802. PWM mode may be used for in-band communication at a lower speed than either a typical operating speed or a maximum operating speed of the link. In various types of links, any other mode generally used as a link management interface may be substituted for PWM mode for phase 802, where the SoC sets the remote device in loopback mode by means of Remote Register Access Protocol (RRAP) commands. SoC command 812.1 (RRAP: LOOPBACK_EN) directs the remote device to enable a loopback to route received signals back through the link to the source. After the remote device acknowledges that the loopback is enabled by sending response 822.1 (RRAP:WR_RESP) to the SoC, the SoC directs the remote device to configure its link interface for high-speed communication by sending command 812.2 (RRAP:CONFIG_HS). When the remote device is configured for high-speed communication, it sends response 822.2 (RRAP:WR_RESP) to the SoC and the link is ready to enter the next phase of the self-test.

In some embodiments, the next two partial tActivate phases 803.1 and 803.2 may be a single continuous phase. Before the high-speed part of the test, the SoC physical layer is isolated from the SoC physical-layer adapter and other upstream components. Initially, both the SoC and the remote device go into suspended STALL states 813.1, 813.2, 823.1 and 823.2. While the remote device remains in STALL state 823.2, the SoC initiates the logical isolation 813.3 of its module interface (e.g., RMMI). This is done to exclude physical-layer (e.g., M-PHY) inputs from the rest of the SoC during the high-speed test, and to prevent the returning test signal patterns from entering the SoC transmitter and receiver controllers through the module interface (e.g., RMMI). The tActivate time may be on the order of 0.1 ms including the isolation step 813.3.

High-speed test phase 804 is the compliance margining stage. This process is usable with any selected “high” speed (e.g., MIPI HS-GEARs 1-4). The SoC physical layer 832 (e.g., MPHY) drives a pre-determined test pattern 814.1. The test pattern 814.1 typically includes groups of signal bursts arranged in complementary patterns. In some embodiments, test pattern 814.1 may be a standard pattern such as CRPAT, CJTPAT, Linear Feedback Shift Register (LFSR) or a scrambler with a CRC polynomial.

In some embodiments, each lane of the link may have its own dedicated test generation/checker block in the SoC physical layer. Alternatively, more than one, or even all, the lanes may share a single test generation/checker block. In some embodiments, generated test pattern data may be sent to a multiplexer that combines it with function data. Additionally or alternatively, the data may be serialized by a PISO (parallel in serial out) analog circuit for transmission. When the data reaches the remote device, it traverses the loopback at a predetermined location such as the remote physical-layer adapter. The loopback sends the received data 824.1 back through the link to the SoC physical layer. The round-trip path through the link enables end-to-end system margining. The pattern returning from the loopback, if serial, may be received at a SIPO (serial in parallel out) to separate the effects of different lanes. In some embodiments, the returning pattern is not retimed or passed to an elastic buffer; this avoids obscuration of any timing errors originating in the link or loopback. A compliance checker module compares the original test pattern to the returned test pattern from the loopback. Mismatches and status metrics are captured in status registers.

After the end signal 814.2 of test pattern 814.1 is sent, looped back, and returns as returning end signal 824.2. In phase 805, the remote device may return to suspended STALL state 825. Meanwhile, test software in the SoC or in a fabric-connected module may read the status register and logs the collected margining data. In phase 806, to terminate the test, the SoC physical layer may drive the LINE-RESET 816. This transitions the SoC and remote device out of test mode. Phase 807, following the LINE-RESET, may be functional mode, in which the link may commence normal operation, or a return to test mode for another test.

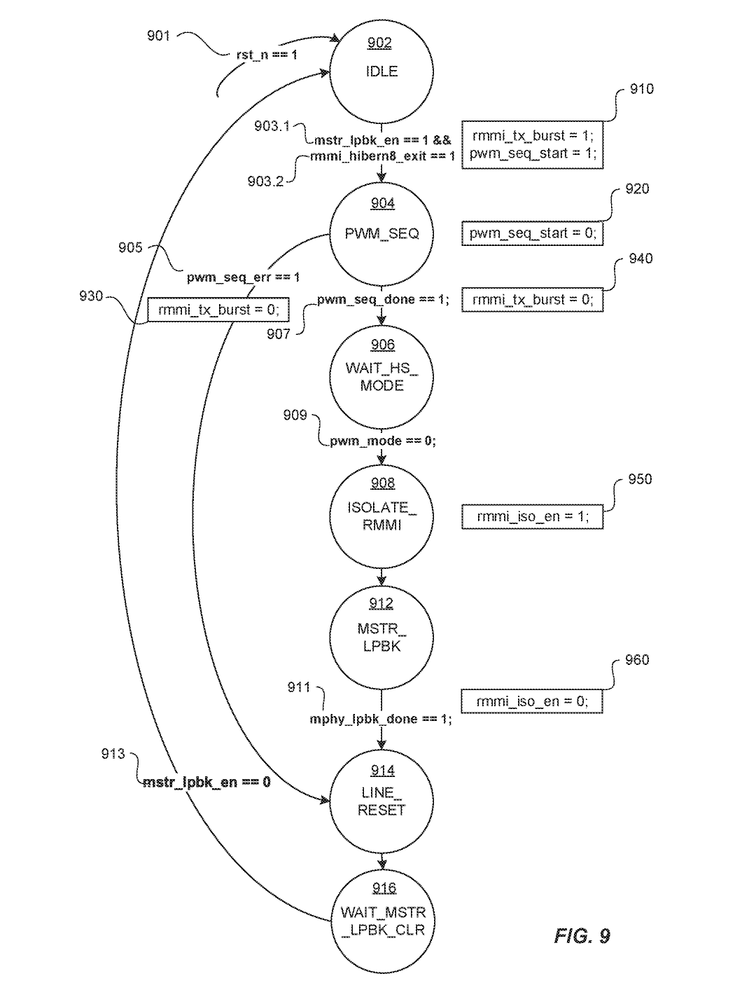

FIG. 9 is a state machine for link interface self-testing. A power-on reset signal 901, rst_n, to the main SoC controller brings the state machine to IDLE state 902. From IDLE state 902, signal 903.1, mstr_lpbk_en==1 from a register such as a CSR to the transmit controller starts the test software to enable a master loopback. Additionally, signal 903.2, rmmi_hibern8_exit from the physical layer to the transmit controller brings the module interface out of the hibern8 suspended state and into PWM traffic mode. Signals 910, rmmi_tx_burst==1; from the SoC controller to the physical layer and pwm_seq_start==1; internal to the state machine send a burst from the transmit controller to the physical-layer and enable the start of a PWM sequence, respectively.

The state machine then transitions to state 904, PWM_SEQ, in which the SoC and the remote device are both in PWM mode for the PWM sequence. Internal signal 920, pwm_seq_start==0; indicates that the PWM sequence is in progress (i.e., does not need to be started). If the PWM sequence is successfully completed (e.g., the master loopback is in place and functioning), internal signal 907, pwm_seq_done==1; may trigger a signal 940, rmmi_tx_burst==0 to the physical layer to stop the transmission bursts and an accompanying transition to state 906, WAIT_HS_MODE, in which the state machine waits for both ends of the link to leave PWM mode and enter HS mode.

Signal 909, pwm_mode==0 indicates that both linked devices have exited PWM mode and triggers a transition to state 908, ISOLATE RMMI, in which signal 950, rmmi_iso_en==1; is sent to the physical layer to enable blocking of the module interface between the physical layer and the physical-layer adapter. This prevents “normal” operating signals to and from the SoC controller from mixing with the test-pattern signals exchanged between the link interfaces of the SoC and the remote device during the HS part of the self-test.

The state machine then automatically transitions to state 912, MSTR_LPBK, in which the physical layers and/or physical-layer adapters of the SoC and the remote device exchange high-speed test patterns. The results may be collected and checked by the SoC physical layer with no involvement of the main SoC controller. When the state machine receives signal 911, mphy_lpbk_done==1 the loopback test is complete and the physical layer is finished sending the outgoing test patterns and checking the returning test patterns. Signal 960, rmmi_iso_en==0; is sent to the physical layer to disable the isolator and unblock the module interface. Signal 911, mphy_lpbk_done==1 also triggers a transition to the LINE-RESET state 914, in which the SoC resets the remote device to a normal operating configuration at the end of the self-test. An automatic transition to state 916, WAIT_MSTR_LPBK_CLR, follows. In this state the system clears registers associated with loopback test configuration. On receiving signal 913, mstr_lpbk_en==0, indicating that the master loopback configuration has been disabled, the state machine returns to IDLE state 902.

If internal signal 905, pwm_seq_err==1 indicates an error in the PWM sequence during PWM_SEQ state 904, the state machine sends signal 930, rmmi_tx_burst==0 to stop the transmission bursts from the physical layer and triggers a transition to LINE_RESET state 914.

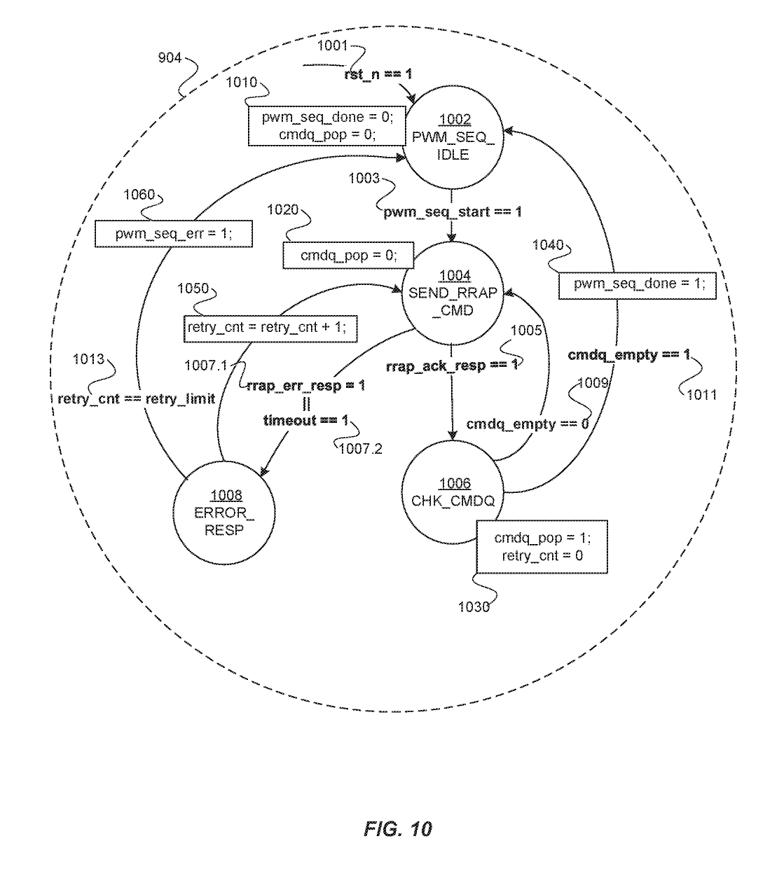

FIG. 10 is a sub-state diagram for the PWM_SEQ state of the previous state diagram. State 1002, PWM_SEQ_IDLE, is the default state produced by signal 1001, rst_n==1, a power-on reset, being sent to the loopback. Signal 1010, pwm_seq_done=0; cmdq_pop=0; is produced to indicate that the PWM sequence is presently unfinished and the command queue is presently “full;” that is, none of the commands have been retrieved and sent. From PWM_SEQ_IDLE state 1002, internal signal 1003, pwm_seq_start==1 enables the PWM_SEQ sub-state machine 904 to start. The pwm_seq_start==1 signal 1003 also triggers a transition to state 1004, SEND_RRAP_CMD, in which commands are retrieved from the command queue (CMDQ) register and transmitted in PWM mode by the physical layer. Examples of CMDQ commands include, without limitation, enabling the loopback at the remote device, speed of the HS mode (e.g., gear and rate) and beginning or ending a burst of pulses during HS pattern testing. Upon entering state 1004, SEND_RRAP_CMD, signal 1020 cmdq_pop=0; is sent to refill the command queue if needed. This is somewhat redundant when transitioning to state 1004, SEND_RRAP_CMD, from state 1002, PWM_SEQ_IDLE, but not when returning from state 1006, WAIT_RRAP_RESP or state 1008, ERROR_RESP.

While in state 1004, SEND_RRAP_CMD, the state machine may receive signal 1005, rrap_ack_resp==1, indicating that a valid acknowledgment of the sent command has been received at the physical layer. This produces a transition to state 1006, WAIT_RRAP_RESP, in which the state machine waits for the remote device's RRAP response. If signal 1009, cmdq_empty==0 is received, it means that one or more commands remain in the command queue; accordingly, it triggers a return to state 1004, SEND_RRAP_CMD, to send the next command in the queue. When all the commands in the queue have been successfully executed, the state machine receives signal 1011, cmdq_empty==1. This causes the state machine to generate internal signal 1040, pwm_seq_done=1; to indicate the end of the PWM sequence.

Alternatively, the state machine in state 1004, SEND_RRAP_CMD, may receive signal 1007.1, rrap_err_resp=1 from the physical layer, indicating receipt of a NACK; the sent command could not be acknowledged because of an error. Another possibility is that the state machine in state 1004, SEND_RRAP_CMD, may receive signal 1007.2, timeout==1 from the physical layer, indicating that the state machine's internal RRAP watchdog timer has expired with no response received from remote device. Either of signals 1007.1 or 1007.2 triggers a state transition to state 1008, ERROR_RESP, from which the error can be handled. Initially the state machine tries to resend the signal, automatically returning to state 1004, SEND_RRAP_CMD. To avoid a system hang, a limit may be placed on the number of retries before a reset; each time the RRAP transmission is retried, the state machine sends signal 1050, retry_cnt=retry_cnt+1; to increment a counter in a register such as the CSR. When the counter reaches its predetermined limit, the state machine in state 1008, ERROR_RESP, will receive signal 1013, retry_cnt==retry_limit from the counter register. This signal prevents yet another direct return to state 1004, SEND_RRAP_CMD. Instead, the state machine returns to state 1002, PWM_SEQ_IDLE as if a power-on reset had just occurred, and begins the process again.

### Examples

Example 1 includes a system-on-chip which comprises a physical layer and a physical-layer adapter coupled to the physical layer. The system-on-chip further comprises logic coupled to the physical-layer adapter. The logic is to initiate a self-test on a link interface between the system-on-chip and a remote device. In addition, the system-on-chip includes a pattern generator coupled to a transmit lane of the physical layer. The pattern generator is to generate test-pattern-generating instructions associated with the self-test.

In Example 2, the system-on-chip includes an isolator that prevents the physical layer from sending signals to a receiver controller or receiving signals from a transmitter controller.

In Example 3, the system-on-chip includes a fabric-coupled register storing at least one of the test-pattern-generating instructions or test results.

In Example 4, the system-on-chip includes a pattern checker coupled to a receive lane of the physical layer. The pattern checker is to receive test results from the remote device.

In Example 5, the system-on-chip includes a multiplexer combining a transmitter controller output and an output of the pattern generator into a transmit path of the physical layer.

In Example 6, the pattern generator and the pattern checker are combined within a single module.

Example 7 includes a system which comprises a host physical layer associated with a host device. The system includes a remote physical layer associated with a remote device and an interface to link the host physical layer and the remote physical layer. The remote device comprises a loopback to direct a signal transmitted from the host device back to the remote device. The loopback is configurable by the host physical layer.

In Example 8, the system further includes an isolator between the host physical layer and a communication controller on the host device. The isolator is configurable by the host physical layer.

In Example 9, the loopback is configured in a physical-layer adaptor on the remote device.

In Example 10, the system further includes a transmit pad and a receive pad within the interface. The subset of an available set of lanes in the transmit pad are configured into the loopback.

Example 11 includes a non-transitory machine-readable storage medium containing instructions that, when executed, cause a machine to trigger a link interface to generate a control signal in an in-band protocol; configure a remote device to a loopback mode using the in-band protocol through one or more lanes of a communication link; send a test pattern to a remote device; and receive a returning pattern from the remote device.

In Example 12, the non-transitory machine-readable storage medium is to cause a machine to calculate an operating margin of the link interface based on the returning pattern and the test pattern.

In Example 13, the in-band protocol is MIPI.

In Example 14, the non-transitory machine-readable storage medium is to cause a machine to trigger the link interface to generate a control signal in the in-band protocol comprises a reset of the link interface.

In Example 15, the non-transitory machine-readable storage medium is to cause a machine to configure the remote device in the loopback mode using the in-band protocol comprises configuring the remote device during operation of the link interface in a first mode. Further, to send the test pattern to the remote device and to receive a returning pattern from the remote device comprise transmission of the test pattern and collection of the returning pattern during operation of the link interface in a second mode. The first mode differs from the second mode.

In Example 16, the first mode is a low-speed mode and the second mode is a high-speed mode.

In Example 17, the first mode comprises pulse-width modulation.

In Example 18, the test pattern comprises at least one of a Compliant Random Pattern and a Compliant Jitter Tolerance Pattern.

In Example 19, the non-transitory machine-readable storage medium is to cause the machine to further output the calculated operating margin.

In Example 20, the operating margin includes a bit error rate.

The preceding Description and accompanying Drawings describe examples of embodiments in some detail to aid understanding. However, the scope of protection may also include equivalents, permutations, and combinations that are not explicitly described herein. Only the claims appended here (along with those of parent, child, or divisional patents, if any) define the limits of the protected intellectual-property rights.

We claim:

1. A system-on-chip, comprising:
a physical layer;
a physical-layer adapter coupled to the physical layer;
logic coupled to the physical-layer adapter wherein the logic is to initiate a self-test on a link interface between the system-on-chip and a remote device; and
a pattern generator coupled to a transmit lane of the physical layer, the pattern generator to generate test-pattern-generating instructions associated with the self-test.

2. The system-on-chip of claim 1 further comprising an isolator that prevents the physical layer from sending signals to a receiver controller or receiving signals from a transmitter controller.

3. The system-on-chip of claim 1 further comprising a fabric-coupled register storing at least one of the test-pattern-generating instructions or test results.

4. The system-on-chip of claim 1 further comprising a pattern checker coupled to a receive lane of the physical layer, the pattern checker to receive test results from the remote device.

5. The system-on-chip of claim 1 further comprising a multiplexer combining a transmitter controller output and an output of the pattern generator into a transmit path of the physical layer.

6. The system-on-chip of claim 5, wherein the pattern generator and the pattern checker are combined within a single module.

7. A system, comprising:
a host physical layer associated with a host device;
a remote physical layer associated with a remote device;
an interface to link the host physical layer and the remote physical layer,
wherein the remote device comprises a loopback to direct a signal transmitted from the host device back to the remote device, and
wherein the loopback is configurable by the host physical layer.

8. The system of claim 7 further comprising an isolator between the host physical layer and a communication controller on the host device,
wherein the isolator is configurable by the host physical layer.

9. The system of claim 7, wherein the loopback is configured in a physical-layer adaptor on the remote device.

10. The system of claim 7 further comprising a transmit pad and a receive pad within the interface wherein a subset of an available set of lanes in the transmit pad are configured into the loopback.

11. A non-transitory machine-readable storage medium containing instructions that, when executed, cause a machine to:
trigger a link interface to generate a control signal in an in-band protocol;
configure a remote device to a loopback mode using the in-band protocol through one or more lanes of a communication link;
send a test pattern to a remote device; and
receive a returning pattern from the remote device.

12. The non-transitory machine-readable storage medium of claim 11 containing instructions that, when executed, cause the machine to calculate an operating margin of the link interface based on the returning pattern and the test pattern.

13. The non-transitory machine-readable storage medium of claim 11, wherein the in-band protocol is Mobile Industry Processing Interface.

14. The non-transitory machine-readable storage medium of claim 11, wherein to trigger the link interface to generate a control signal in the in-band protocol comprises a reset of the link interface.

15. The non-transitory machine-readable storage medium of claim 11, wherein to configure the remote device in the loopback mode using the in-band protocol comprises configuring the remote device during operation of the link interface in a first mode;
wherein to send the test pattern to the remote device and to receive a returning pattern from the remote device comprise transmission of the test pattern and collection of the returning pattern during operation of the link interface in a second mode; and
wherein the first mode differs from the second mode.

16. The non-transitory machine-readable storage medium of claim 15, wherein the first mode is a low-speed mode and the second mode is a high-speed mode.

17. The non-transitory machine-readable storage medium of claim 15, wherein the first mode comprises pulse-width modulation.

18. The non-transitory machine-readable storage medium of claim 11, wherein the test pattern comprises at least one of a Compliant Random Pattern and a Compliant Jitter Tolerance Pattern.

19. The non-transitory machine-readable storage medium of claim 12 containing instructions that, when executed, cause the machine to further output the calculated operating margin.

20. The non-transitory machine-readable storage medium of claim 12, wherein the operating margin includes a bit error rate.
